(19) United States
(12) Patent Application Publication
(10) Pub. No.: US 2026/0318965 A1
(43) Pub. Date: Oct. 15, 2026

(54) METHOD FOR MEASURING RECEIVED POWER, METHOD FOR CALCULATING POWER REFLECTION EFFICIENCY, NON-TRANSITORY COMPUTER READABLE MEDIUM STORING A PROGRAM FOR MEASURING RECEIVED POWER, AND NON-TRANSITORY COMPUTER READABLE MEDIUM STORING A PROGRAM FOR CALCULATING POWER REFLECTION EFFICIENCY

(71) Applicant: AGC Inc., Tokyo (JP)

(72) Inventor: Kumiko KAMBARA, Tokyo (JP)

(73) Assignee: AGC Inc., Tokyo (JP)

(21) Appl. No.: 19/692,170

(22) Filed: May 29, 2026

Related U.S. Application Data
(63) Continuation of application No. PCT/JP2024/038228, filed on Oct. 25, 2024.

(30) Foreign Application Priority Data
Nov. 30, 2023 (JP) 2023-202313

(51) Int. Cl. G01R 29/08; H01Q 15/14

(52) U.S. Cl. CPC G01R 29/0821; G01R 29/0878; H01Q 15/14

(57) ABSTRACT

A method for measuring received power of an electromagnetic-wave reflecting apparatus having a metasurface or a regular reflection surface is provided. The method includes: in an anechoic chamber where a VNA is connected to transmitting and receiving antennas with fixed relative positions, transmitting a radio wave in a predetermined band (1 MHz to 300 GHz) to be incident on an electromagnetic-wave reflecting apparatus at a first specified incident angle; receiving a reflected wave at a first specified reflection angle and measuring first received power in a specified frequency range by the VNA; transmitting a radio wave to be incident on a reflection plate including a metal reflection surface at a second specified incident angle; and receiving a reflected wave at a second specified reflection angle and measuring second received power in the specified frequency range by the VNA.

### INCORPORATION BY REFERENCE

This application is based upon and claims the benefit of priority from Japanese patent application No. 2023-203013 filed on Nov. 30, 2023, and PCT application No. PCT/JP2024/038228 filed on Oct. 25, 2024, the disclosure of which is incorporated herein in its entirety by reference.

### BACKGROUND

The present disclosure relates to a method for measuring received power, a method for calculating power reflection efficiency, a non-transitory computer readable medium storing a program for measuring received power, and a non-transitory computer readable medium storing a program for calculating power reflection efficiency.

In the fifth-generation (hereinafter referred to as “5G”) mobile communication standard, high-speed and large-capacity communication is expected. However, since radio waves having a highly straight-traveling property are used in 5G, there may be places where such radio waves are less likely to reach. Means for sending radio waves to target terminal apparatuses or radio devices are required in a place where a plurality of metal machines are present, such as a factory, or in a place where a large number of reflections occur from wall surfaces or roadside trees, such as an area with a plurality of buildings. The above means are also required in a place where a Non-Line-Of-Sight (NLOS) spot in which an antenna of a base station cannot be directly seen is generated, such as a medical site, an event venue, and a large commercial facility. The use of terahertz bands or sub-terahertz bands is expected in the next-generation sixth-generation, and hence the above means are also required.

In recent years, a reflection surface having an artificial surface referred to as a “metasurface” has been developed. A metasurface is formed of periodic structures or patterns that are finer than the wavelength and designed so as to reflect radio waves in a desired direction (see, for example, Non patent Literature 1). Since a metasurface makes it possible to obtain a desired reflection angle while maintaining a planar arrangement/configuration, it effectively functions as a reflector even in an environment in which there is not enough space to install a large number of reflection panels. It has been proposed that a radio transmission system which includes an electromagnetic-wave reflecting apparatus having a metasurface or a regular reflection surface is introduced into a production line of a factory or a plant (see, for example, Patent Literature 1 and Patent Literature 2).
Patent Literature 1: International Patent Publication No. WO 2021/199503
Patent Literature 2: International Patent Publication No. WO 2021/199504
Non Patent Literature 1: Diaz-Rubio et al., Sci. Adv. 2017:3: e1602714 1

### SUMMARY

It should be noted that when a conventional radio transmission system is introduced, arrangement of an electromagnetic-wave reflecting apparatus having a metasurface or a regular reflection surface and a base station, and other configurations are designed based on power reflection efficiency of the electromagnetic-wave reflecting apparatus. Therefore, it is required to appropriately evaluate power reflection efficiency. Further, it is required to appropriately evaluate power reflection efficiency not only when a conventional radio transmission system is introduced but also when an electromagnetic-wave reflecting apparatus having a metasurface or a regular reflection surface is disposed.

However, a method for appropriately evaluating power reflection efficiency of an electromagnetic-wave reflecting apparatus having a metasurface or a regular reflection surface has not been established. Further, in order to evaluate power reflection efficiency, it is required to appropriately evaluate received power in an electromagnetic-wave reflecting apparatus.

Therefore, an object of the present disclosure is to provide a method for measuring received power by which it is possible to appropriately measure received power in an electromagnetic-wave reflecting apparatus having a metasurface or a regular reflection surface, and a method for calculating power reflection efficiency by which it is possible to appropriately calculate power reflection efficiency in an electromagnetic-wave reflecting apparatus having a metasurface or a regular reflection surface.

A method for measuring reception power according to an embodiment of the present disclosure comprises: a first process of, in an anechoic chamber in which a vector network analyzer connected to a transmitting antenna and a receiving antenna of which relative positions are fixed is disposed, causing the transmitting antenna to transmit a radio wave in a predetermined band selected from frequency bands of 1 MHz or higher and 300 GHz or lower, and making the radio wave incident on an electromagnetic-wave reflecting apparatus at a first specified incident angle; a second process of receiving a reflected wave of the radio wave incident on the electromagnetic-wave reflecting apparatus in the first process by the receiving antenna disposed in a direction of a first specified reflection angle with respect to the electromagnetic-wave reflecting apparatus, and measuring first received power in a specified frequency range by the vector network analyzer; a third process of, in the anechoic chamber, causing the transmitting antenna to transmit a radio wave in the predetermined band and making the radio wave incident on a reflection plate including a metal reflection surface at a second specified incident angle; and a fourth process of receiving a reflected wave of the radio wave incident on the metal reflection surface in the third process by the receiving antenna disposed in a direction of a second specified reflection angle with respect to the reflection plate including the metal reflection surface, and measuring second received power in the specified frequency range by the vector network analyzer.

A method for measuring received power by which it is possible to appropriately measure received power in an electromagnetic-wave reflecting apparatus having a metasurface or a regular reflection surface, and a method for calculating power reflection efficiency by which it is possible to appropriately calculate power reflection efficiency in an electromagnetic-wave reflecting apparatus having a metasurface or a regular reflection surface are provided.

The above and other objects, features and advantages of the present disclosure will become more fully understood from the detailed description given hereinbelow and the accompanying drawings.

### BRIEF DESCRIPTION OF DRAWINGS

FIG. 1 is a diagram showing an example of a configuration of an electromagnetic-wave reflecting apparatus 60 using a reflection panel 10 according to an embodiment;

FIG. 2 is a diagram showing an example of a configuration of an electromagnetic-wave reflecting fence 100 formed by connecting electromagnetic-wave reflecting apparatuses 60-1, 60-2, and 60-3 to each other;

FIG. 3 is a diagram showing an example of a layer structure of the reflection panel 10;

FIG. 4 is a diagram showing an example of a layer structure of a reflection panel 10A;

FIG. 5 is a diagram showing an example of a configuration of a unit cell 20 of a conductive pattern 15 composed of hollow patterns 151;

FIG. 6 is a diagram showing an example of a measuring device disposed in an anechoic chamber 101;

FIG. 7A is a diagram for explaining an example of a method for calculating power reflection efficiency according to the embodiment;

FIG. 7B is a diagram for explaining an example of the method for calculating power reflection efficiency according to the embodiment;

FIG. 8 is a flowchart showing an example of processes of a method for measuring received power and the method for calculating power reflection efficiency according to the embodiment;

FIG. 9A is a diagram showing an example of results of measurement of a distance from a transmitting antenna 115Tx to an electromagnetic-wave reflecting apparatus 60A on a path of an incident wave and a distance from the electromagnetic-wave reflecting apparatus 60A to a receiving antenna 115Rx on a path of a reflected wave when the correction value was 1 or smaller and a slight deviation in the measurement distance did not cause a significant change regarding the electromagnetic-wave reflecting apparatus 60A;

FIG. 9B is a diagram showing an example of results of measurement of a distance from the transmitting antenna 115Tx to the electromagnetic-wave reflecting apparatus 60A on a path of an incident wave and a distance from the electromagnetic-wave reflecting apparatus 60A to the receiving antenna 115Rx on a path of a reflected wave when the correction value was 1 or smaller and a slight deviation in the measurement distance did not cause a significant change regarding the electromagnetic-wave reflecting apparatus 60A;

FIG. 9C is a diagram showing an example of a configuration of a reflection surface of the electromagnetic-wave reflecting apparatus 60A; and

FIG. 10 is a diagram showing an example of a result in which a quadratic curve is fitted to the results shown in FIG. 9A.

### DESCRIPTION OF EMBODIMENTS

Hereinafter, an embodiment to which a method for measuring received power, a method for calculating power reflection efficiency, a non-transitory computer readable medium storing a program for measuring received power, and a non-transitory computer readable medium storing a program for calculating power reflection efficiency according to the present disclosure are applied will be described. In the following description, the same elements are denoted by the same reference symbols, and redundant descriptions thereof may be omitted.

Prior to describing the method for measuring received power, the method for calculating power reflection efficiency, the program for measuring received power, and the program for calculating power reflection efficiency according to the present disclosure, a configuration of an electromagnetic-wave reflecting apparatus having a metasurface or a regular reflection surface included in a radio transmission system that may be used outdoors or indoors will be described below. The radio transmission system includes a base station in addition to the above electromagnetic-wave reflecting apparatus, and constructs a radio communication area in an outdoor or indoor facility.

In the description given below, an XYZ coordinate system is defined. A direction parallel to an X-axis (an X-direction), a direction parallel to a Y-axis (a Y-direction), and a direction parallel to a Z-axis (a Z-direction) are orthogonal to each other. Further, for convenience of explanation, a −Z direction side may be referred to as a lower side or bottom, and a +Z direction side may be referred to as an upper side or top. Further, a plan view refers to an XY plan view. Further, in the following description, the length, the thickness, and the like of each component may be exaggerated so as to make the structure easier to understand. Further, regarding the words such as parallel, a right angle, orthogonal, horizontal, vertical, up/down, and the like, deviations that do not impair the effects of the embodiments are allowed.

In the embodiment, in the radio transmission system used indoors and outdoors, blind zones are reduced by using the electromagnetic-wave reflecting apparatus. The term “blind zone” used in this specification refers to a zone in which the received power is lowered by 10 dB or more due to the presence of a shielding object compared with the surrounding receiving environment in which there is no shielding object. In general, electromagnetic waves of 3 THz or lower are referred to as radio waves. In this specification, communication waves transmitted from a base station are referred to as “radio waves”, and electromagnetic waves in general are referred to as “electromagnetic waves”.

The blind zone includes not only a two-dimensional area but also a three-dimensional space. If production equipment, a sensor, a mobile communication terminal, or the like equipped with a radio communication function is positioned in the blind zone, it becomes difficult to transmit/receive signals to/from the base station. Therefore, the electromagnetic-wave reflecting apparatus is introduced to reduce the blind zones and improve the radio wave environment.

### Embodiment

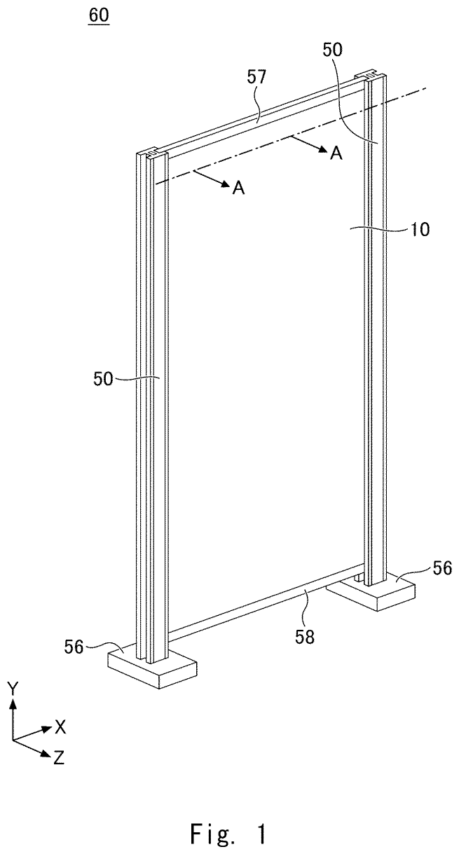

FIG. 1 is a diagram showing an example of a configuration of an electromagnetic-wave reflecting apparatus 60 using a reflection panel 10 according to the embodiment. The electromagnetic-wave reflecting apparatus 60 includes the reflection panel 10 and frames 50 for holding the reflection panel 10. In the coordinate system shown in FIG. 1, in a state where the electromagnetic-wave reflecting apparatus 60 is installed, the width or the lateral direction of the reflection panel 10 is defined as an X direction; the height or the longitudinal direction thereof is defined as a Y direction; and the thickness direction thereof is defined as a Z direction. The reflection panel 10 reflects electromagnetic waves in the gigahertz to terahertz bands, such as microwaves, millimeter waves, and submillimeter waves, and reflects, for example, electromagnetic waves of 1 MHz or higher and 300 GHz or lower.

As an example, radio waves transmitted and received by the base station in the radio transmission system including the electromagnetic-wave reflecting apparatus 60 are preferably radio waves in the frequency band of 1 MHz to 300 GHz including the frequency band of Sub-6 such as the 5th generation mobile communication system (5G) and the millimeter wave band. At present, the frequency band of Sub-6 and the 28 GHz band included in the millimeter wave band are used, and in the next-generation 6G mobile communication standards, it is expected that the frequency band will be extended to the sub-terahertz band. By using such a high frequency band, the communication bandwidth is greatly extended, and a large amount of data communication can be performed with a small delay.

Further, radio waves transmitted and received by the base station may be in Long Term Evolution (LTE), LTE-Advanced (LTE-A), Ultra Mobile Broadband (UMB), or Citizens Broadband Radio Service (CBRS). Further, radio waves transmitted and received by the base station may be in IEEE802.11 (Wi-Fi (registered trademark), IEEE802.16 (WiMAX (registered trademark)), IEEE802.20, Ultra-Wideband (UWB), Bluetooth (registered trademark), Low Power Wide Area (LPWA), or the like.

The reflection panel 10 may have a specular reflection surface in which the incident angle and the exit angle of an electromagnetic wave are equal to each other, or a metasurface in which a reflection direction is controlled. The reflection panel 10 may be a combination of a specular reflection surface and a metasurface. The metasurface may be designed not only to provide a non-specular reflection surface which reflects an incident electromagnetic wave in a direction different from the incident angle, but also to control a diffusion state of an electromagnetic wave.

The metasurface of the reflection panel 10 reflects both horizontally and vertically polarized waves in a controlled direction. Horizontally polarized waves are those that oscillate in a direction parallel to the ground or in the lateral direction with respect to the direction of propagation. Vertically polarized waves are those that oscillate in a direction perpendicular to the ground or in the longitudinal direction with respect to the direction of propagation. By forming a conductor pattern constituting a metasurface in a hollow rectangular shape, both horizontally and vertically polarized waves can be reflected in a controlled direction.

The frames 50 hold two sides of the reflection panel 10 along the height direction when the reflection panel 10 is installed. In addition to the frames 50, a top frame 57 for holding the upper end of the reflection panel 10 and a bottom frame 58 for holding the lower end thereof may be provided. In this case, the frames 50, the top frame 57, and the bottom frame 58 constitute a frame for holding the whole peripheral edges of the reflection panel 10. The frames 50 may be referred to as “side frames” because of the positional relationship with respect to the top and the bottom frames 57 and 58. Leg parts 56 for supporting the frames 50 may be provided. As shown in FIG. 1, in a case where the electromagnetic-wave reflecting apparatus 60 is installed in an upright position on an installation surface, the electromagnetic-wave reflecting apparatus 60 is preferably equipped with the leg parts 56, but the leg parts 56 are not indispensable. The leg parts 56 may be made movable by providing them with casters. Alternatively, the reflection panel 10 may be installed on a wall surface without providing it with the leg parts 56, or may be hung from the ceiling.

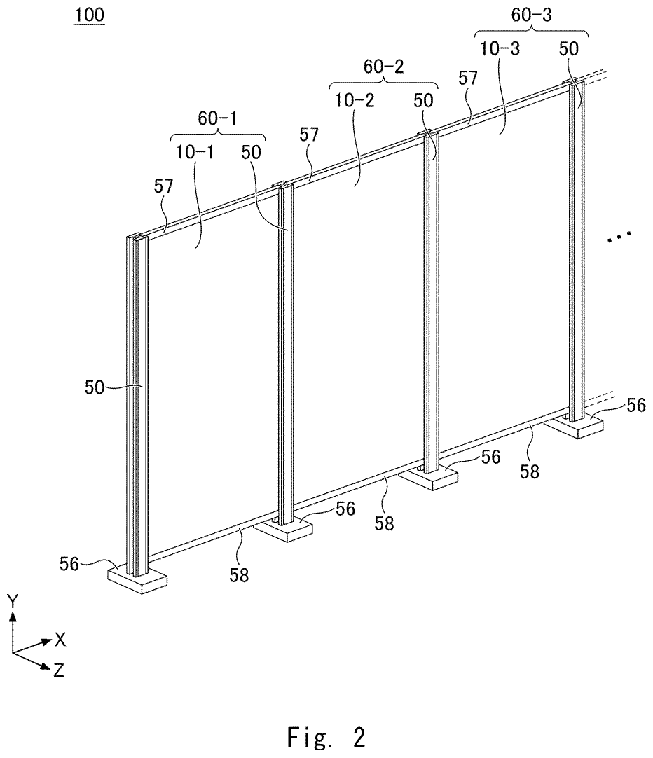

FIG. 2 is a diagram showing an example of a configuration of an electromagnetic-wave reflecting fence 100 formed by connecting electromagnetic-wave reflecting apparatuses 60-1, 60-2, and 60-3 to each other. In FIG. 2, the electromagnetic-wave reflecting fence 100 is formed by connecting three of the electromagnetic-wave reflecting apparatuses 60-1, 60-2, and 60-3 (hereinafter they may be collectively referred to as “electromagnetic-wave reflecting apparatuses 60” as appropriate), but the number of electromagnetic-wave reflecting apparatuses 60 to be connected to each other is not limited to any particular number.

The electromagnetic-wave reflecting apparatuses 60-1, 60-2, and 60-3 include reflection panels 10-1, 10-2, and 10-3, respectively. By holding the reflection panels adjacent to each other by the frames 50, the electromagnetic-wave reflecting fence 100 in which the reflection panels are connected to each other in the X direction can be obtained. Each of the reflection panels 10-1, 10-2, and 10-3 (hereinafter they may be collectively referred to as “reflection panels 10” as appropriate) has, at least in a part thereof, a reflection surface formed of a hollow rectangular conductive pattern. Thus, both horizontally and vertically polarized waves are reflected in a controlled direction.

### <Layer Structure of the Reflection Panel 10>

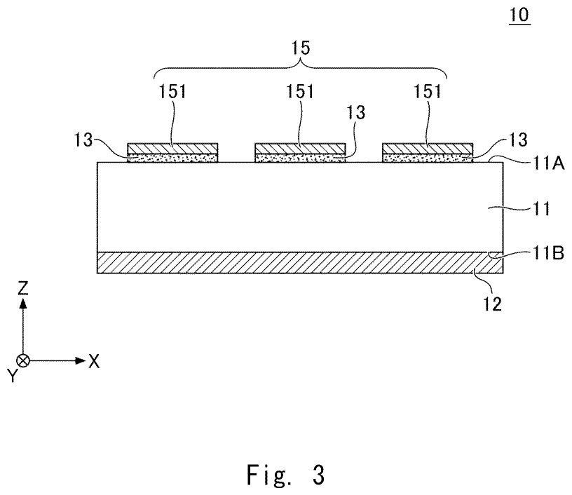

FIG. 3 is a diagram showing an example of a layer structure of the reflection panel 10. The layer structure shown in FIG. 3 is a layer structure in an XZ cross section of the reflection panel 10, and a lamination direction is the thickness direction (Z direction) of the reflection panel 10. FIG. 3 shows, as an example, a cross section of the reflection panel 10 when viewed from the lower side (the −Y direction side).

The reflection panel 10 includes a dielectric layer 11, a periodic conductive pattern 15 provided on one surface 11A of the dielectric layer 11, and a ground layer 12 provided on the other surface 11B of the dielectric layer 11. The conductive pattern 15 forms a reflection surface of the reflection panel 10, and reflects electromagnetic waves of 1 MHz or higher and 300 GHz or lower in a predetermined direction.

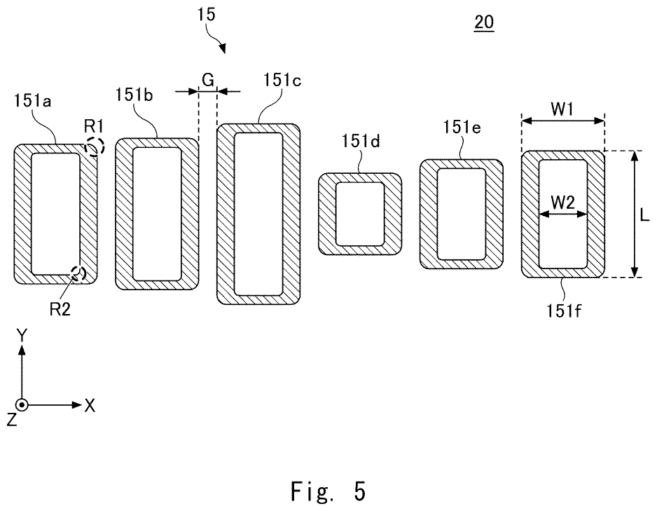

The conductive pattern 15 includes a periodic array of a plurality of hollow patterns 151. A specific shape of each of the hollow patterns 151 will be described later with reference to FIG. 5. The hollow pattern is formed of a good conductor such as Ag, Cu, Ni, or Al as an example, and has a thickness of 0.01 mm or larger and 0.05 mm or smaller as an example. When it has a thickness of less than 0.01 mm, the surface resistivity increases, and hence it becomes difficult to maintain a high reflection efficiency. When it has a thickness of 0.05 mm or more, it becomes difficult to maintain the flatness of the reflection surface. The surface of the conductive pattern 15 may be protected by a transparent film having a dielectric constant and a dielectric loss tangent equal to those of the dielectric layer 11.

As an example, the hollow pattern 151 is bonded to the dielectric layer 11 by an adhesive layer 13. As an example, the adhesive layer 13 is not applied to the entire surface of the dielectric layer 11, and an amount of the adhesive layer 13 required to stably support the hollow pattern 151 is used instead. This configuration aims to minimize the influence of the adhesive layer 13 on the dielectric constant of the dielectric layer 11. The area occupied by the adhesive layer 13 does not need to be exactly the same as the area occupied by the conductive pattern 15, and a slight deviation may be allowed as long as the hollow pattern 151 can be stably bonded to the dielectric layer 11. For example, if the area occupancy rate of the conductive pattern 15 to the dielectric layer 11 is 10.0% or higher and 45.0% or lower, the area occupancy rate of the adhesive layer 13 to the dielectric layer 11 is 9.0% or higher and 50.0% or lower.

If the area occupancy rate of the conductive pattern 15 is less than 10.0%, it becomes difficult to achieve desired reflection characteristics and reflection efficiency. If the area occupancy rate of the conductive pattern 15 exceeds 45.0%, it becomes difficult to maintain the transparency of the reflection panel 10. However, for applications that do not require the transparency, the area occupancy rate of the conductive pattern 15 may be increased to 45.0% or higher to give a high priority to the reflection efficiency.

The adhesive layer 13 is a material by which the conductive pattern 15 can be bonded to the dielectric layer 11, and a thermoplastic resin such as a vinyl acetate resin, an acrylic resin, a cellulose resin, or a silicone resin may be used for the adhesive layer 13. The thickness of the adhesive layer 13 is a thickness that enables the conductive pattern 15 to be stably bonded to the dielectric layer 11, and is, for example, 0.002 mm or more and 0.050 mm or less. In order to secure the adhesive strength, the thickness thereof is preferably 0.010 mm or more and 0.050 mm or less.

The dielectric layer 11 is an insulating polymer film made of polycarbonate, cycloolefin polymer (COP), polyethylene terephthalate (PET), a fluorine resin, or the like, and has a thickness of about 0.3 mm to 1.0 mm. The dielectric layer 11 may be any material having a relative dielectric constant and a dielectric loss tangent suitable for achieving a target reflection characteristic.

The ground layer 12 may be formed of a material the same as or different from the conductive pattern 15. The ground layer 12 forms a predetermined parasitic capacitance between it and the conductive pattern 15. The amount of phase delay is determined by the parasitic capacitance formed between the conductive pattern 15 and the ground layer 12.

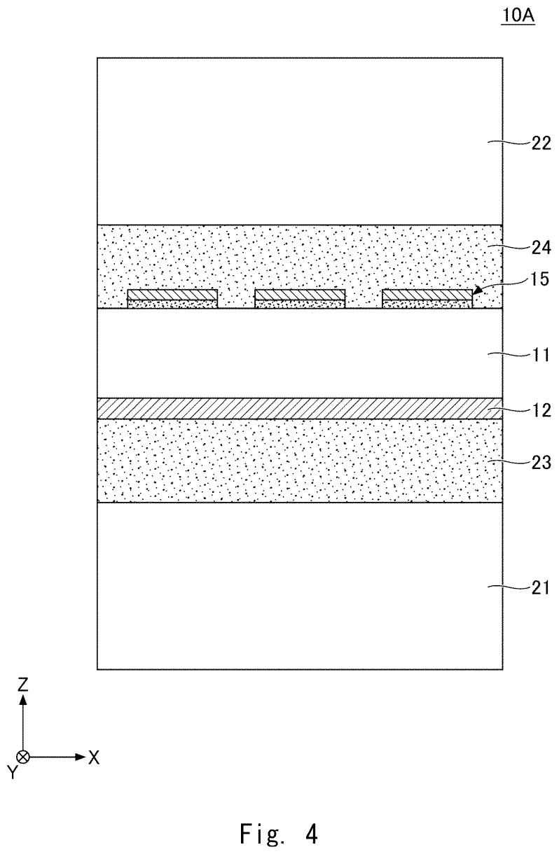

FIG. 4 is a diagram showing an example of a layer structure of a reflection panel 10A. This layer structure has a structure in which the layer structure shown in FIG. 3 is sandwiched between two dielectric substrates 21 and 22. The dielectric substrate 21 is bonded to the ground layer 12 by an adhesive layer 23. The dielectric substrate 22 is bonded to the conductive pattern 15 side of the dielectric layer 11 by an adhesive layer 24. The dielectric substrates 21 and 22 are transparent to electromagnetic waves in the gigahertz to terahertz bands, specifically, electromagnetic waves of 1 MHz or higher and 3 THz or lower, for example, electromagnetic waves of 1 MHz or higher and 300 GHz or lower. Each of the dielectric substrates 21 and 22 is preferably formed of a material excellent in impact resistance, durability, and transparency as the outermost layer of the reflection panel 10A. Polycarbonate, an acrylic resin, PET, or the like may be used for the dielectric substrates 21 and 22. The thickness of each of the dielectric substrates 21 and 22 may be selected from the range of, for example, from 1.0 mm to 10.0 mm as appropriate in accordance with a place where it is installed. The thicknesses of the dielectric substrates 21 and 22 may be the same as or different from each other.

The adhesive layer 23 protects the surface of the ground layer 12, and adheres and holds the dielectric substrate 21. The adhesive layer 24 protects the surface of the conductive pattern 15, and adheres and holds the dielectric substrate 22. The adhesive layers 23 and 24 are desirably durable and moisture-resistant, and for example, an ethylene-vinyl acetate (EVA) copolymer or a cycloolefin polymer (COP) can be used. The thicknesses of the adhesive layers 23 and 24 are appropriately determined in a range of 10 μm to 400 μm so that the dielectric substrates 21 and 22 can be bonded.

By covering the conductive pattern 15 with the adhesive layer 24 and then bonding the dielectric substrate 22 thereto, moisture and air are prevented from entering the surface of the conductive pattern 15, and hence the reflection surface is prevented from deteriorating. By covering the ground layer 12 with the adhesive layer 23 and then bonding the dielectric substrate 21 thereto, moisture and air are prevented from entering the surface of the ground layer 12, and hence the surface of the ground layer 12 is prevented from deteriorating. As a result, the capacitance between the ground layer 12 and the conductive pattern 15 is maintained at a constant value, and the designed magnitude of a phase delay can be maintained. That is, the reflection efficiency of a radio wave in the designed direction can be maintained.

### <Configuration Example of the Hollow Pattern>

FIG. 5 is a diagram showing an example of a configuration of a unit cell 20 of the conductive pattern 15 composed of the hollow patterns 151.

In the example shown in FIG. 5, the unit cell 20 includes six hollow patterns 151a, 151b, 151c, 151d, 151e, and 151f. The direction of a width W1 and the direction of a length L of each of the hollow patterns 151a to 151f correspond to the width (X) direction and the height (Z) direction of the reflection panel 10 shown in FIG. 2A, respectively. Although the hollow patterns 151a to 151f have the same width W1 as each other and the lengths L different from each other, the central axes of their lengths are aligned (the Y coordinate positions of the central axes are the same). The pitches or intervals G between them in the X direction are the same. The phase of reflection is controlled by the shapes and the sizes of the hollow patterns 151a to 151f, and a reflection beam is formed in a desired direction by superimposing reflected waves. In this example, the unit cell 20 is designed so as to reflect a beam of a reflected wave of an electromagnetic wave incident normally (an incident angle of 0°) in a direction of 50° from the normal.

The hollow patterns 151a, 151b, 151c, 151d, 151e, and 151f (hereinafter may collectively be referred to as “hollow patterns 151”) are hollow with a width W2. The hollow pattern has a rectangular ring shape in an XZ plane view. Note that ½ of the difference between the width W1 of the outer periphery of each of the hollow patterns 151 and the width W2 of the inner periphery of the same is the width of the line segment of the hollow pattern 151 in the vertical direction. Similarly, the thickness of the line segment of the hollow pattern 151 in the horizontal direction is determined in accordance with the area of the hollow. Both vertically and horizontally polarized waves can be reflected by the line segments of the hollow pattern 151 in the vertical and the horizontal directions.

Each corner part of the hollow pattern 151 on the outer edge thereof may be a right angle without curvature or may be curved with a radius of curvature R1. In the case of a right angle, the radius of curvature R1=0.0 mm. Each corner part of the inner periphery of the hollow pattern 151 is curved with a radius of curvature R2. The radius of curvature R1 is smaller than or equal to the radius of curvature R2. By rounding each of the corner parts of the hollow pattern 151, in particular, each of the corner parts thereof on the inner edge side, with a predetermined radius of curvature, the concentration of current is prevented and the reflection efficiency is maintained. Specifically, by rounding each of the corner parts of the hollow pattern 151 on the inner edge side with the radius of curvature R2 of 1/10 or larger and ½ or smaller of the width W1, the hollow pattern 151 can respond to both vertically and horizontally polarized waves while reducing the concentration of current.

The conductive pattern 15 is a periodic pattern in which the unit cells 20 are repeatedly disposed in the X and the Z directions. By providing a reflection surface formed by the conductive pattern 15 in at least a part of the reflection panel 10, both incident horizontally and vertically polarized electromagnetic waves can be reflected in a controlled direction.

### <Method for Measuring Received Power and Method for Calculating Power Reflection Efficiency According to the Embodiment>

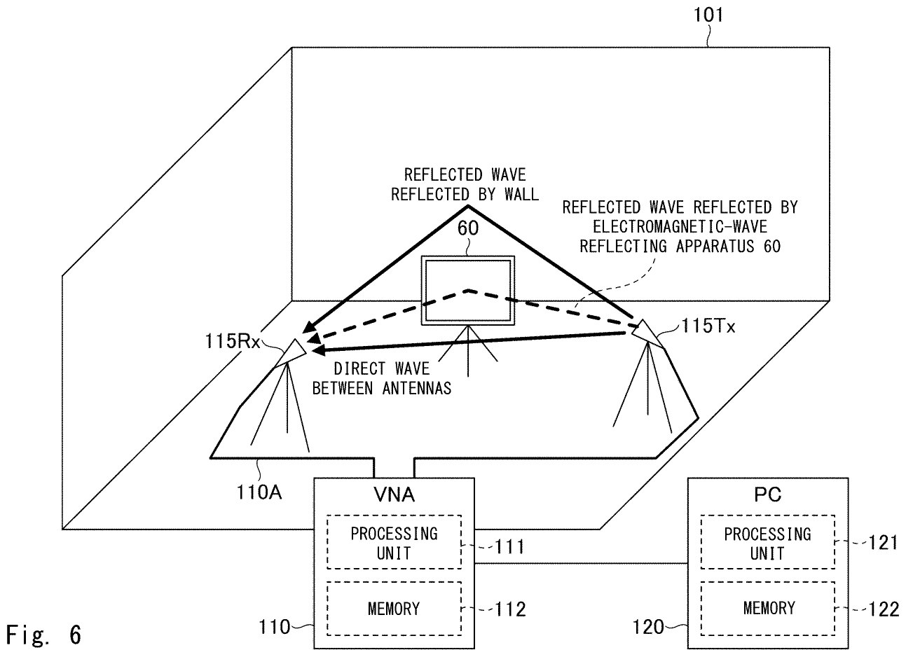

First, an example of a measuring device which measures received power of the electromagnetic-wave reflecting apparatus 60 will be described below with reference to FIG. 6.

### <Measuring Device>

FIG. 6 is a diagram showing an example of a measuring device disposed in an anechoic chamber 101. Note that a Vector Network Analyzer (VNA) 110 is used as a measuring device. A transmitting antenna 115Tx and a receiving antenna 115Rx are connected to the VNA 110 through cables 110A. Further, the transmitting antenna 115Tx is oriented to the electromagnetic-wave reflecting apparatus 60, and the receiving antenna 115Rx is disposed in the reflecting direction of the electromagnetic-wave reflecting apparatus 60.

Further, a Personal Computer (PC) 120 is connected to the VNA 110. Note that, in FIG. 6, the PC 120 is disposed outside the anechoic chamber 101 as an example, but may be disposed inside the anechoic chamber 101.

For example, the electromagnetic-wave reflecting apparatus 60, the transmitting antenna 115Tx, and the receiving antenna 115Rx are disposed at predetermined height positions on the floor in the anechoic chamber 101 by tripods or the like. When measurement is performed, the relative positions of the transmitting antenna 115Tx and the receiving antenna 115Rx are fixed. Further, the position of the electromagnetic-wave reflecting apparatus 60 relative to the transmitting antenna 115Tx and the receiving antenna 115Rx is fixed.

When the angle of the electromagnetic-wave reflecting apparatus 60 with respect to each of the transmitting antenna 115Tx and the receiving antenna 115Rx is changed according to whether the electromagnetic-wave reflecting apparatus 60 is a metasurface which performs non-specular reflection or a reflecting apparatus which performs specular reflection, the angle of the electromagnetic-wave reflecting apparatus 60 may be changed by fixing the transmitting antenna 115Tx and the receiving antenna 115Rx, or the positions (the orientations) of the transmitting antenna 115Tx and the receiving antenna 115Rx may be changed by fixing the angle of the electromagnetic-wave reflecting apparatus 60. Further, both the angle of the electromagnetic-wave reflecting apparatus 60 and the positions (the orientations) of the transmitting antenna 115Tx and the receiving antenna 115Rx may be changed.

### <VNA 110>

The VNA 110 includes a processing unit 111 and a memory 112 in addition to a transmitting circuit unit which transmits a transmission signal to the transmitting antenna 115Tx and a receiving circuit unit which measures power (received power) of a reception signal received by the receiving antenna 115Rx. In FIG. 6, the transmitting circuit unit and the receiving circuit unit of the VNA 110 are omitted.

Note that a description will be given below of a configuration in which the transmitting antenna 115Tx and the receiving antenna 115Rx are connected to one VNA 110. However, the VNA 110 may be configured so that it is separated into a VNA connected to the transmitting antenna 115Tx and a VNA connected to the receiving antenna 115Rx, and these two VNAs may be connected to each other through an optical cable or the like, to thereby operate in cooperation with each other.

The VNA 110 includes therein a computer system which implements the processing unit 111 and the memory 112. The computer system is implemented by a computer including a Central Processing Unit (CPU), a Random Access Memory (RAM), a Read Only Memory (ROM), an input/output interface, an internal bus, and the like. The processing unit 111 is a unit representing the function of a program executed by the computer system of the VNA 110 as a functional block. Further, the memory 112 functionally represents the memory of the computer system of the VNA 110.

### <Processing Unit 111>

The processing unit 111 controls the transmitting circuit unit and the receiving circuit unit of the VNA 110, to thereby perform a process of causing the transmitting antenna 115Tx to emit a radio wave and a process of measuring received power of a radio wave received by the receiving antenna 115Rx. These processes are implemented by the method for measuring received power according to the embodiment.

In the process of causing the transmitting antenna 115Tx to emit a radio wave, the processing unit 111 controls the transmitting circuit unit to cause the transmitting antenna 115Tx to transmit a radio wave in a predetermined band selected from frequency bands of 1 MHz or higher and 300 GHz or lower. An operator of the PC 120 inputs a desired band to the PC 120 and the PC 120 transmits data indicating a predetermined band to the VNA 110, whereby the predetermined band is selected. Note that the predetermined band may be selected directly to the VNA 110 without using the PC 120.

In the process of measuring received power, the processing unit 111 controls the receiving circuit unit to scan the frequency of received power within a specified frequency range and measure the received power in the electromagnetic-wave reflecting apparatus 60. The processing unit 111 can discriminate among a reflected wave reflected by the electromagnetic-wave reflecting apparatus 60, a reflected wave reflected by the inner wall of the anechoic chamber 101, and a direct wave by using a time domain function.

The reflected wave reflected by the electromagnetic-wave reflecting apparatus 60 is a radio wave that is transmitted from the transmitting antenna 115Tx, reflected by the electromagnetic-wave reflecting apparatus 60, and reaches the receiving antenna 115Rx. The reflected wave reflected by the inner wall of the anechoic chamber 101 is a radio wave that is transmitted from the transmitting antenna 115Tx, reflected by the inner wall of the anechoic chamber 101, and reaches the receiving antenna 115Rx. The direct wave is a radio wave that is transmitted from the transmitting antenna 115Tx and directly reaches the receiving antenna 115Rx.

Further, in the method for calculating power reflection efficiency according to the embodiment, power reflection coefficients are calculated based on received power. This process may be performed by either the processing unit 111 of the VNA 110 or a processing unit 121 of the PC 120, or may be performed by the processing units 111 and 121 in a shared manner. As an example, a configuration in which the processing unit 111 of the VNA 110 calculates power reflection coefficients based on received power will be described below. That is, as an example, a configuration in which the processing unit 111 of the VNA 110 executes the calculation process by the method for calculating power reflection efficiency will be described below. Note that the details of the method for calculating power reflection efficiency will be described later with reference to FIGS. 6 to 8.

### <Memory 112>

The memory 112 stores programs, data, and the like required for the processing unit 111 of the VNA 110 to execute the calculation process by the method for calculating power reflection efficiency.

### <PC 120>

The PC 120 includes therein a computer system which implements the processing unit 121 and a memory 122. The computer system is implemented by a computer including a CPU, a RAM, a ROM, an input/output interface, an internal bus, and the like. The processing unit 121 is a unit representing the function of a program executed by the computer system of the PC 120 as a functional block. Further, the memory 122 functionally represents the memory of the computer system of the PC 120.

As described above, in this embodiment, a configuration in which the processing unit 111 of the VNA 110 executes the calculation process by the method for calculating power reflection efficiency is described. However, the processing unit 121 of the PC 120 may execute the calculation process by the method for calculating power reflection efficiency, or the processing units 111 and 121 may execute the calculation process by the method for calculating power reflection efficiency in a shared manner. The memory 122 stores programs, data, and the like required for the processing unit 121 to execute processes.

### <Method for Calculating Power Reflection Efficiency According to the Embodiment>

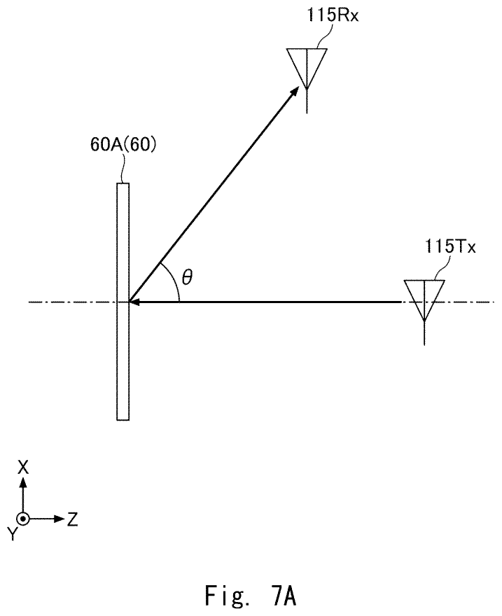

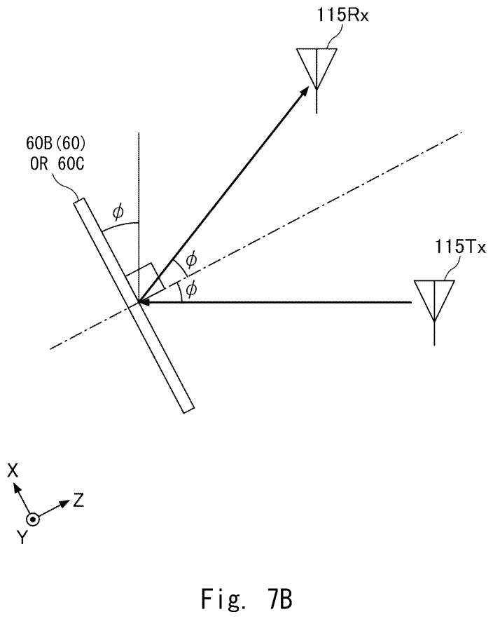

Each of FIGS. 7A and 7B is a diagram for explaining an example of a method for calculating power reflection efficiency according to the embodiment. FIGS. 7A and 7B show the same XYZ coordinates as those shown in FIGS. 1 to 5.

FIGS. 7A and 7B show simplified positional relationships among the transmitting antenna 115Tx, the receiving antenna 115Rx, and the electromagnetic-wave reflecting apparatus 60 in a two-dimensional plane. In the following description, the electromagnetic-wave reflecting apparatus 60 having a metasurface may be referred to as an electromagnetic-wave reflecting apparatus 60A, and the electromagnetic-wave reflecting apparatus 60 having a regular reflection surface may be referred to as an electromagnetic-wave reflecting apparatus 60B. When the electromagnetic-wave reflecting apparatuses 60A and 60B are not particularly distinguished from each other, they are simply referred to as the electromagnetic-wave reflecting apparatuses 60.

Further, when the reflection efficiency of each of the electromagnetic-wave reflecting apparatuses 60A and 60B is calculated, a reflection coefficient obtained from the received power measured by the electromagnetic-wave reflecting apparatus 60 composed of a perfect conductor is used. In the following description, the electromagnetic-wave reflecting apparatus 60 composed of a perfect conductor is referred to as an electromagnetic-wave reflecting apparatus 60C. The electromagnetic-wave reflecting apparatus 60C is an example of a reflection plate having a metal reflection surface. The electromagnetic-wave reflecting apparatus 60C needs only to have a flat metal surface as its reflection surface, and as an example, a metal plate made of aluminum can be used as the electromagnetic-wave reflecting apparatus 60C. Note that, since the reflection surface only needs to be a flat metal surface, a reflection plate formed by attaching aluminum foil to a resin substrate or the like may be used as the electromagnetic-wave reflecting apparatus 60C.

FIG. 7A shows the electromagnetic-wave reflecting apparatus 60A having a metasurface, and FIG. 7B shows the electromagnetic-wave reflecting apparatus 60B having a regular reflection surface. Further, the electromagnetic-wave reflecting apparatus 60C composed of a perfect conductor performs specular reflection in a manner similar to that by which the electromagnetic-wave reflecting apparatus 60B performs it. Therefore, in FIG. 7B, the electromagnetic-wave reflecting apparatus 60C is denoted as the electromagnetic-wave reflecting apparatus 60B (60) or 60C.

### <Details of the Method for Calculating Power Reflection Efficiency According to the Embodiment>

As shown in FIG. 7A, in the case of the electromagnetic-wave reflecting apparatus 60A, as an example, the angles and the distances of the electromagnetic-wave reflecting apparatus 60A, the transmitting antenna 115Tx, and the receiving antenna 115Rx are set in advance so that, regarding the electromagnetic-wave reflecting apparatus 60A, the transmitting antenna 115Tx is positioned in the direction in which the incident angle is 0 degrees, and the receiving antenna 115Rx is positioned in the direction in which the reflection angle when a radio wave is incident at an incident angle of 0 degrees is θ degrees. The angle θ is an angle formed by the transmitting antenna 115Tx and the receiving antenna 115Rx with respect to the electromagnetic-wave reflecting apparatus 60A. In FIG. 7A, a normal line of the reflection surface is shown by a dot-dash line. A distance between the electromagnetic-wave reflecting apparatus 60A and the transmitting antenna 115Tx on the path of an incident wave is equal to a distance between the electromagnetic-wave reflecting apparatus 60A and the receiving antenna 115Rx on the path of a reflected wave. As an example, in FIG. 7A, the normal line of the reflection surface of the electromagnetic-wave reflecting apparatus 60A is oriented in the horizontal direction. Note that the incident angle may not be 0 degrees. The electromagnetic-wave reflecting apparatus 60A reflects radio waves in a direction shifted by θ degrees with respect to the incident angle.

Further, when received power of the electromagnetic-wave reflecting apparatus 60C is measured under the same reflection condition as that when received power of the electromagnetic-wave reflecting apparatus 60A is measured, the angle of the electromagnetic-wave reflecting apparatus 60C is adjusted without changing the positions of the transmitting antenna 115Tx and the receiving antenna 115Rx as shown in FIG. 7B so that the direction of the normal line of the reflection surface of the electromagnetic-wave reflecting apparatus 60C passes through the center of the angle θ shown in FIG. 7A. Thus, the incident angle and the reflection angle of the electromagnetic-wave reflecting apparatus 60C are φ degrees, and θ=2φ holds. The angle 2φ is an angle formed by the transmitting antenna 115Tx and the receiving antenna 115Rx with respect to the electromagnetic-wave reflecting apparatus 60C. A distance between the electromagnetic-wave reflecting apparatus 60A and the transmitting antenna 115Tx on the path of an incident wave is equal to a distance between the electromagnetic-wave reflecting apparatus 60A and the receiving antenna 115Rx on the path of a reflected wave.

The same reflection condition means that the angle θ in FIG. 7A is equal to the sum (2φ) of the incident angle φ and the reflection angle φ in FIG. 7B, and the distance between the electromagnetic-wave reflecting apparatus 60A and each of the transmitting antenna 115Tx and the receiving antenna 115Rx in FIG. 7A is equal to the distance between the electromagnetic-wave reflecting apparatus 60C and each of the transmitting antenna 115Tx and the receiving antenna 115Rx in FIG. 7B.

As described above, under the same reflection condition, received power P1 of a reflected wave reflected by the electromagnetic-wave reflecting apparatus 60A and received power P2 of a reflected wave reflected by the electromagnetic-wave reflecting apparatus 60C are measured, a power reflection coefficient Γ1 is calculated from the received power P1, and a power reflection coefficient Γ2 is calculated from the received power P2.

Then, power reflection efficiency H of the electromagnetic-wave reflecting apparatus 60A is calculated, using the power reflection coefficients Γ1 and Γ2 calculated for the electromagnetic-wave reflecting apparatuses 60A and 60 C under the same reflection condition, by dividing the power reflection coefficient Γ1 by the power reflection coefficient Γ2. In this way, the power reflection efficiency H of the electromagnetic-wave reflecting apparatus 60A is calculated by normalizing the power reflection coefficient Γ1 of the electromagnetic-wave reflecting apparatus 60A by the power reflection coefficient Γ2 of the electromagnetic-wave reflecting apparatus 60C composed of a perfect conductor.

Since the electromagnetic-wave reflecting apparatus 60C composed of a perfect conductor performs specular reflection, the incident angle and the reflection angle are equal to each other. However, in the electromagnetic-wave reflecting apparatus 60A having a metasurface, the incident angle and the reflection angle are different from each other, and thus it is required to correct the power reflection efficiency H (=Γ1/Γ2) that is calculated from the power reflection coefficients Γ1 and Γ2 calculated for the electromagnetic-wave reflecting apparatuses 60A and 60 C under the same reflection condition. The power reflection efficiency H of the electromagnetic-wave reflecting apparatus 60A having a metasurface is set to a value obtained by dividing Γ1/Γ2 by a correction value.

When a reflected electric field in an ideal metasurface with no reflection loss is denoted as E_{MR}, and a reflected electric field in a reflection surface composed of a perfect conductor is denoted as E_{PEC}, a correction value ε_{P} can be expressed by |E_{MR}/E_{PEC}|².

|E_{MR}/E_{PEC}| is expressed by the following expression (1) or (2).

$$\begin{matrix}[ Expression 1 ] & \\ \vert \frac{{E}_{MR}}{{E}_{PEC}} \vert = \frac{\sqrt{\vert cos θ \vert}}{\vert cos θ \vert} & ( 1 )\end{matrix}$$

$$\begin{matrix}[ Expression 2 ] & \\ \vert \frac{{E}_{MR}}{{E}_{PEC}} \vert = \frac{\sqrt{\vert cos {θ}_{i} \cdot cos {θ}_{r} \vert}}{\vert cos φ \vert} & ( 2 )\end{matrix}$$

Note that θ is an incident angle to a metasurface, and φ is a reflection angle in the case of the corresponding regular reflection. When the reflection angle of the metasurface is θ=50° or θr=50°, the incident angle is θi=0°, and the reflection angle φ of the regular reflection is 25°, the correction value ε_{P} is 0.7826.

Note that a method for obtaining the power reflection efficiency H of the electromagnetic-wave reflecting apparatus 60A having a metasurface has been described above with reference to FIGS. 7A and 7B. In the case of the electromagnetic-wave reflecting apparatus 60B having a regular reflection surface, the measurement of received power and the calculation of the power reflection coefficient Γ2 based on the received power are performed under the reflection condition where both the incident angle and the reflection angle are φ as shown in FIG. 7B. Therefore, a correction based on a difference between radar cross-sectional areas as in the case of the electromagnetic-wave reflecting apparatus 60A having a metasurface is not required.

Under the same reflection condition, the received power P1 of a reflected wave reflected by the electromagnetic-wave reflecting apparatus 60B and the received power P2 of a reflected wave reflected by the electromagnetic-wave reflecting apparatus 60C are measured, the power reflection coefficient Γ1 is calculated from the received power P1, and the power reflection coefficient Γ2 is calculated from the received power P2. Then, the power reflection efficiency H (=Γ1/Γ2) of the electromagnetic-wave reflecting apparatus 60B can be calculated, using the power reflection coefficients Γ1 and Γ2 calculated for the electromagnetic-wave reflecting apparatuses 60A and 60 C under the same reflection condition, by dividing the power reflection coefficient Γ1 by the power reflection coefficient Γ2.

### <Flowchart>

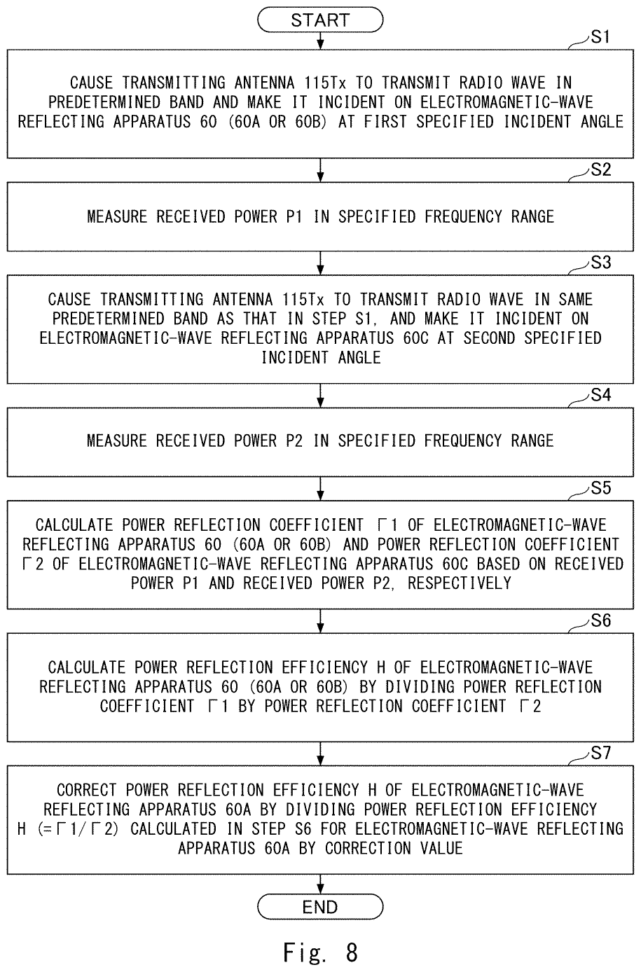

FIG. 8 is a flowchart showing an example of processes of the method for measuring received power and the method for calculating power reflection efficiency according to the embodiment. In the following description, as an example, the processing unit 111 of the VNA 110 executes the processes shown in FIG. 8. The processing unit 111 executes a program for measuring received power and a program for calculating power reflection efficiency for implementing the method for measuring received power and the method for calculating power reflection efficiency, whereby the processes shown in FIG. 8 are executed.

The processing unit 111 controls the transmitting circuit unit to cause the transmitting antenna 115Tx to transmit a radio wave in a predetermined band selected from frequency bands of 1 MHz or higher and 300 GHz or lower, and make the radio wave incident on the electromagnetic-wave reflecting apparatus 60 (60A or 60B) at a first specified incident angle (Step S1). The first specified incident angle is 0 degrees as an example in the case of the electromagnetic-wave reflecting apparatus 60A, and an incident angle (φ) determined by the positional relationship between the transmitting antenna 115Tx and the receiving antenna 115Rx in the case of the electromagnetic-wave reflecting apparatus 60B. The incident angle determined by the positional relationship between the transmitting antenna 115Tx and the receiving antenna 115Rx is an angle specified by the design of the electromagnetic-wave reflecting apparatus 60B. Step S1 is an example of a process 1.

The receiving antenna 115Rx disposed in the direction of a first specified reflection angle with respect to the electromagnetic-wave reflecting apparatus 60 (60A or 60B) receives a reflected wave of the radio wave incident on the electromagnetic-wave reflecting apparatus 60 (60A or 60B) in a first process, and the processing unit 111 measures the received power P1 in a specified frequency range (Step S2). Step S2 is an example of a process 2. The received power P1 is an example of first received power. The first specified reflection angle is a reflection angle θ specified by the design of the electromagnetic-wave reflecting apparatus 60A in the case of the electromagnetic-wave reflecting apparatus 60A, and an angle equal to the incident angle in Step S1 in the case of the electromagnetic-wave reflecting apparatus 60B. The specified frequency range is a frequency band including a plurality of measurement points by the time domain function, and can be set in the VNA 110. As an example, when a predetermined band selected from frequency bands of 1 MHz or higher and 300 GHz or lower is 28 GHz, the specified frequency range is 22 GHz to 40 GHz, and the plurality of measurement points are a plurality of frequencies set every 10 MHz within a range from 22 GHz to 40 GHz.

The processing unit 111 controls the transmitting circuit unit to cause the transmitting antenna 115Tx to transmit a radio wave in the same predetermined band as that in Step S1, and make the radio wave incident on the electromagnetic-wave reflecting apparatus 60C at a second specified incident angle (Step S3). When the electromagnetic-wave reflecting apparatus 60A is used in Step S1, the second specified incident angle is a half angle of the reflection angle θ specified by the design of the electromagnetic-wave reflecting apparatus 60A, while when the electromagnetic-wave reflecting apparatus 60B is used in Step S1, it is an angle equal to the first specified incident angle of the electromagnetic-wave reflecting apparatus 60B in Step S1. Step S3 is an example of the process 1.

The receiving antenna 115Rx disposed in the direction of a second specified reflection angle with respect to the electromagnetic-wave reflecting apparatus 60C receives a reflected wave of the electromagnetic wave incident on the electromagnetic-wave reflecting apparatus 60C in a third process, and the processing unit 111 measures the received power P2 in the specified frequency range (Step S4). Step S4 is an example of a process 4. The received power P2 is an example of the second received power. When the electromagnetic-wave reflecting apparatus 60A is used in Step S2, the second specified reflection angle is a half angle of the reflection angle θ of the electromagnetic-wave reflecting apparatus 60A, while when the electromagnetic-wave reflecting apparatus 60B is used in Step S2, it is an angle equal to the first specified reflection angle of the electromagnetic-wave reflecting apparatus 60B in Step S2.

Note that, in the processes of Steps S1 to S4, the processes of Steps S1 and S2 may be executed after the processes of Steps S3 and S4.

The position of the electromagnetic-wave reflecting apparatus 60 (60A or 60B) in Steps S1 and S2 with respect to the transmitting antenna 115Tx and the receiving antenna 115Rx is the same as the position of the electromagnetic-wave reflecting apparatus 60C in Steps S3 and S4 with respect to the transmitting antenna 115Tx and the receiving antenna 115Rx. Note that, as an example, the positions of the electromagnetic-wave reflecting apparatuses 60A and 60B in Steps S1 and S2 are the positions of the centers of gravity of the electromagnetic-wave reflecting apparatuses 60A and 60B.

The processing unit 111 calculates the power reflection coefficient Γ1 of the electromagnetic-wave reflecting apparatus 60 (60A or 60B) and the power reflection coefficient Γ2 of the electromagnetic-wave reflecting apparatus 60C based on the received power P1 and the received power P2, respectively (Step S5). The power reflection coefficient Γ1 is calculated as a reflection coefficient of the S parameter based on the received power P1, and the power reflection coefficient Γ2 is calculated as a reflection coefficient of the S parameter based on the received power P2. Step S5 is an example of a fifth process. The power reflection coefficient Γ1 is an example of a first power reflection coefficient, and the power reflection coefficient Γ2 is an example of a second power reflection coefficient.

The processing unit 111 calculates the power reflection efficiency H of the electromagnetic-wave reflecting apparatus 60 (60A or 60B) by dividing the power reflection coefficient Γ1 by the power reflection coefficient Γ2 (Step S6). Step S6 is an example of a sixth process. In Step S6, the power reflection efficiency H is obtained as Γ1/Γ2.

In the case of the electromagnetic-wave reflecting apparatus 60B, since regular reflection is performed, the incident angle and the reflection angle are equal to each other and correction is thus not required. Therefore, the power reflection efficiency H (=Γ/Γ2) calculated in Step S6 is the power reflection efficiency of the electromagnetic-wave reflecting apparatus 60B.

In the case of the electromagnetic-wave reflecting apparatus 60B, correction is required, and therefore the processing unit 111 executes Step S7.

The processing unit 111 corrects the power reflection efficiency H (=ΓΓ1/Γ2) of the electromagnetic-wave reflecting apparatus 60A by dividing the power reflection efficiency H (=Γ1/Γ2) calculated in Step S6 for the electromagnetic-wave reflecting apparatus 60A by the correction value |EMR/EPEC|² (Step S7). Step S7 is an example of a seventh step.

After Step S7, the processing unit 111 ends the series of processes (End).

### Results of Experiments (Part 1)

Examples 1 to 7 will be described as results of experiments (Part 1).

### Example 1

Example 1 is Example 1 according to the present disclosure. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +25° on an aluminum plate having a thickness of 5.0 mm as an electromagnetic-wave reflecting apparatus 60C composed of a perfect conductor by space propagation through a transmitting antenna 115Tx, a reflected wave was received in the direction of −25° by a receiving antenna 115Rx, and received power P2 at 28.0 GHz was measured at a terminal of the VNA 110 connected to the receiving antenna 115Rx. The size (the length in the X direction×the length in the Y direction) of the aluminum plate was set to 0.2 m×0.2 m, the distance from the transmitting antenna 115Tx to the aluminum plate on the path of the incident wave was set to 1.5 m, and the distance from the aluminum plate to the receiving antenna 115Rx on the path of the reflected wave was set to 1.5 m. The received power P2 was −29.7 dB, and the power reflection coefficient Γ2 was 0.00108.

Next, the radio wave was incident from an angle of +25° on an electromagnetic-wave reflecting apparatus 60B that has a regular reflection surface having a thickness of 5.0 mm by space propagation through the transmitting antenna 115Tx, a reflected wave was received in the direction of −25° by the receiving antenna 115Rx, and received power P1 at a wavelength of 28.0 GHz was measured at a terminal of the VNA 110 connected to the receiving antenna 115Rx. The size (the length in the X direction×the length in the Y direction) of the electromagnetic-wave reflecting apparatus 60B was set to 0.2 m×0.2 m, the distance from the transmitting antenna 115Tx to the electromagnetic-wave reflecting apparatus 60B on the path of the incident wave was set to 1.5 m, and the distance from the electromagnetic-wave reflecting apparatus 60B to the receiving antenna 115Rx on the path of the reflected wave was set to 1.5 m. The received power P1 was −29.8 dB, and the power reflection coefficient Γ1 was 0.00105. The ratio of Γ1/Γ2 was 98.1%. This agreed with the result of the electromagnetic field analysis performed in advance.

### Example 2

Example 2 is Example 2 according to the present disclosure. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +25° on an aluminum plate having a thickness of 5.0 mm as an electromagnetic-wave reflecting apparatus 60C composed of a perfect conductor by space propagation through a transmitting antenna 115Tx, a reflected wave was received in the direction of −25° by a receiving antenna 115Rx, and received power P2 at 28.0 GHz was measured at a terminal of the VNA 110 connected to the receiving antenna 115Rx. The size (the length in the X direction×the length in the Y direction) of the aluminum plate was set to 0.2 m×0.2 m, the distance from the transmitting antenna 115Tx to the aluminum plate on the path of the incident wave was set to 1.5 m, and the distance from the aluminum plate to the receiving antenna 115Rx on the path of the reflected wave was set to 1.5 m. The received power P2 was −29.7 dB, and the power reflection coefficient Γ2 was 0.00108.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +50° by the receiving antenna 115Rx, and received power at 28.0 GHz was measured at a terminal of the VNA 110 connected to the receiving antenna 115Rx. The size (the length in the X direction×the length in the Y direction) of the electromagnetic-wave reflecting apparatus 60A was set to 0.2 m×0.2 m, the distance from the transmitting antenna 115Tx to the electromagnetic-wave reflecting apparatus on the path of the incident wave was set to 1.5 m, and the distance from the electromagnetic-wave reflecting apparatus to the receiving antenna 115Rx on the path of the reflected wave was set to 1.5 m. The received power P1 was −30.8 dB, and the power reflection coefficient Γ1 was 0.00082. The ratio of Γ1/Γ2 was 75.9%. Since the correction value was 0.96, the corrected power reflection efficiency was 79.1%. This agreed with the result of the electromagnetic field analysis performed in advance.

### Example 3

Example 3 is Example 3 according to the present disclosure. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +15° on an aluminum plate having a thickness of 5.0 mm as an electromagnetic-wave reflecting apparatus 60C composed of a perfect conductor by space propagation through a transmitting antenna 115Tx, a reflected wave was received in the direction of −15° by a receiving antenna 115Rx, and received power P2 at 28.0 GHz was measured at a terminal of the VNA 110 connected to the receiving antenna 115Rx. The size (the length in the X direction×the length in the Y direction) of the aluminum plate was set to 0.3 m×0.3 m, the distance from the transmitting antenna 115Tx to the aluminum plate on the path of the incident wave was set to 3.0 m, and the distance from the aluminum plate to the receiving antenna 115Rx on the path of the reflected wave was set to 3.0 m. The received power P2 was −29.7 dB, and the power reflection coefficient Γ2 was 0.00108.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +30° by the receiving antenna 115Rx, and received power P1 at 28.0 GHz was measured at a terminal of the VNA 110 connected to the receiving antenna 115Rx. The size (the length in the X direction×the length in the Y direction) of the electromagnetic-wave reflecting apparatus 60A was set to 0.3 m×0.3 m, the distance from the transmitting antenna 115Tx to the electromagnetic-wave reflecting apparatus 60A on the path of the incident wave was set to 1.5 m, and the distance from the electromagnetic-wave reflecting apparatus 60A to the receiving antenna 115Rx on the path of the reflected wave was set to 1.5 m. The received power P1 was −30.2 dB, and the power reflection coefficient Γ1 was 0.00095. The ratio of Γ1/Γ2 was 88.0%. Since the correction value was 0.98, the corrected power reflection efficiency was 89.8%. This agreed with the result of the electromagnetic field analysis performed in advance.

### Example 4

Example 4 is Example 4 according to the present disclosure. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +15° on an aluminum plate having a thickness of 5.0 mm as an electromagnetic-wave reflecting apparatus 60C composed of a perfect conductor by space propagation through a transmitting antenna 115Tx, a reflected wave was received in the direction of −15° by a receiving antenna 115Rx, and received power at 28.0 GHz was measured at a terminal of the VNA 110 connected to the receiving antenna 115Rx. The size (the length in the X direction×the length in the Y direction) of the aluminum plate was set to 0.5 m×0.2 m, the distance from the transmitting antenna 115Tx to the aluminum plate on the path of the incident wave was set to 8.0 m, and the distance from the aluminum plate to the receiving antenna 115Rx on the path of the reflected wave was set to 8.0 m. The received power P2 was −29.7 dB, and the power reflection coefficient Γ2 was 0.00108.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +45° by the receiving antenna 115Rx, and received power at 28.0 GHz was measured at a terminal of the VNA 110 connected to the receiving antenna 115Rx. The size (the length in the X direction×the length in the Y direction) of the electromagnetic-wave reflecting apparatus 60A was set to 0.2 m×0.2 m, the distance from the transmitting antenna 115Tx to the electromagnetic-wave reflecting apparatus 60A on the path of the incident wave was set to 1.5 m, and the distance from the electromagnetic-wave reflecting apparatus 60A to the receiving antenna 115Rx on the path of the reflected wave was set to 1.5 m. The received power P1 was −30.5 dB, and the power reflection coefficient Γ1 was 0.00089. The ratio of Γ1/Γ2 was 82.4%. However, since the correction value was 0.99, the corrected power reflection efficiency was 83.2%. This agreed with the result of the electromagnetic field analysis performed in advance.

### Example 5

Example 5 is Comparative Example 1. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +25.0° on an aluminum plate having a thickness of 5.0 mm as an electromagnetic-wave reflecting apparatus 60C composed of a perfect conductor by space propagation through a transmitting antenna 115Tx, a reflected wave was received in the direction of −25.0° by a receiving antenna 115Rx, and received power at 28.0 GHz was measured at a terminal of the VNA 110 connected to the receiving antenna 115Rx. The size (the length in the X direction×the length in the Y direction) of the aluminum plate was set to 0.3 m×0.3 m, the distance from the transmitting antenna 115Tx to the aluminum plate on the path of the incident wave was set to 1.0 m, and the distance from the aluminum plate to the receiving antenna 115Rx on the path of the reflected wave was set to 1.0 m. The received power was −29.5 dB, and the power reflection coefficient Γ2 was 0.00112.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +50° by the receiving antenna 115Rx, and received power at 28.0 GHz was measured at a terminal of the VNA 110 connected to the receiving antenna 115Rx. The size (the length in the X direction×the length in the Y direction) of the electromagnetic-wave reflecting apparatus was set to 0.3 m×0.3 m, the distance from the transmitting antenna 115Tx to the electromagnetic-wave reflecting apparatus on the path of the incident wave was set to 0.3 m, and the distance from the electromagnetic-wave reflecting apparatus to the receiving antenna 115Rx on the path of the reflected wave was set to 0.3 m. The received power was-30.5 dB, and the power reflection coefficient was 0.00089 (Γ2). Although the ratio of Γ1/Γ2 was 63.4%, the correction value was 2.12, which exceeded 1. Therefore, the power reflection efficiency was not able to be amended. Further, it did not agree with the result of the electromagnetic field analysis performed in advance.

### Example 6

Example 6 is Comparative Example 2. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +25° on an aluminum plate having a thickness of 5.0 mm as an electromagnetic-wave reflecting apparatus 60C composed of a perfect conductor by space propagation through a transmitting antenna 115Tx, a reflected wave was received in the direction of −25° by a receiving antenna 115Rx, and received power at 28.0 GHz was measured at a terminal of the VNA 110 connected to the receiving antenna 115Rx. The size (the length in the X direction×the length in the Y direction) of the aluminum plate was set to 0.5 m×0.2 m, the distance from the transmitting antenna 115Tx to the aluminum plate on the path of the incident wave was set to 2.9 m, and the distance from the aluminum plate to the receiving antenna 115Rx on the path of the reflected wave was set to 2.9 m. The received power was-29.5 dB, and the power reflection coefficient Γ2 was 0.00112.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +50° by the receiving antenna 115Rx, and received power at 28.0 GHz was measured at a terminal of the VNA 110 connected to the receiving antenna 115Rx. The size (the length in the X direction×the length in the Y direction) of the electromagnetic-wave reflecting apparatus 60A was set to 0.3 m×0.3 m, the distance from the transmitting antenna 115Tx to the electromagnetic-wave reflecting apparatus 60A on the path of the incident wave was set to 0.3 m, and the distance from the electromagnetic-wave reflecting apparatus 60A to the receiving antenna 115Rx on the path of the reflected wave was set to 0.3 m. The received power P1 was −30.9 dB, and the power reflection coefficient Γ1 was 0.00081. Since the ratio of Γ1/Γ2 was 72.3% and the correction value was 2.12, the correction value exceeded 1 and the power reflection efficiency was not able to be corrected. Further, it did not agree with the result of the electromagnetic field analysis performed in advance.

### Example 7

Example 7 is Comparative Example 3. In an anechoic chamber 101 having a length of 5.0 m, a width of 5.0 m, and a height of 3.0 m, a high-frequency signal at a specified frequency of 22.0 GHz to 40.0 GHz was output from a VNA 110, a radio wave was incident from an angle of +30° on an aluminum plate having a thickness of 5.0 mm as an electromagnetic-wave reflecting apparatus 60C composed of a perfect conductor by space propagation through a transmitting antenna 115Tx, a reflected wave was received in the direction of −30° by a receiving antenna 115Rx, and received power at 28.0 GHz was measured at a terminal of the VNA 110 connected to the receiving antenna 115Rx. The size (the length in the X direction×the length in the Y direction) of the aluminum plate was set to 0.5 m×0.2 m, the distance from the transmitting antenna 115Tx to the aluminum plate on the path of the incident wave was set to 2.0 m, and the distance from the aluminum plate to the receiving antenna 115Rx on the path of the reflected wave was set to 2.0 m. The received power P2 was −29.5 dB, and the power reflection coefficient Γ2 was 0.00112.

Next, a radio wave was made incident at an incident angle of 0° on an electromagnetic-wave reflecting apparatus 60A that has a metasurface having a thickness of 5.0 mm by space propagation through the transmitting antenna 115Tx, and a reflected wave was received in the direction of +60° by the receiving antenna 115Rx, and received power at 28.0 GHz was measured at a terminal of the VNA 110 connected to the receiving antenna 115Rx. The size (the length in the X direction×the length in the Y direction) of the electromagnetic-wave reflecting apparatus 60A was set to 0.5 m×0.2 m, the distance from the transmitting antenna 115Tx to the electromagnetic-wave reflecting apparatus 60A on the path of the incident wave was set to 0.3 m, and the distance from the electromagnetic-wave reflecting apparatus 60A to the receiving antenna 115Rx on the path of the reflected wave was set to 0.3 m. The received power was −30.5 dB, and the power reflection coefficient Γ1 was 0.00089. Since the ratio of Γ1/Γ2 was 63.4% and the correction value was 2.02, the correction value exceeded 1 and the power reflection efficiency was not able to be corrected. Further, it did not agree with the result of the electromagnetic field analysis performed in advance.

### Results of Experiments (Part 2)

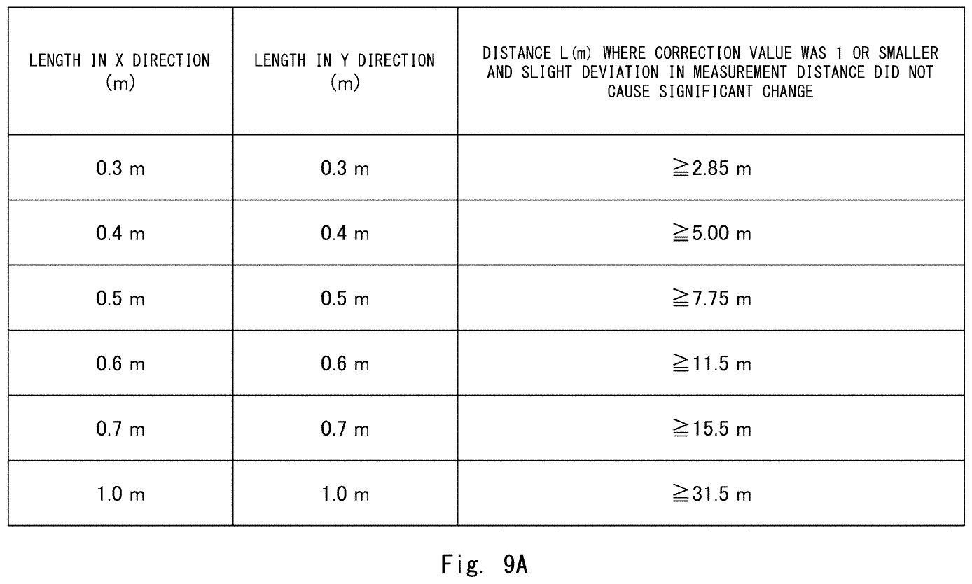

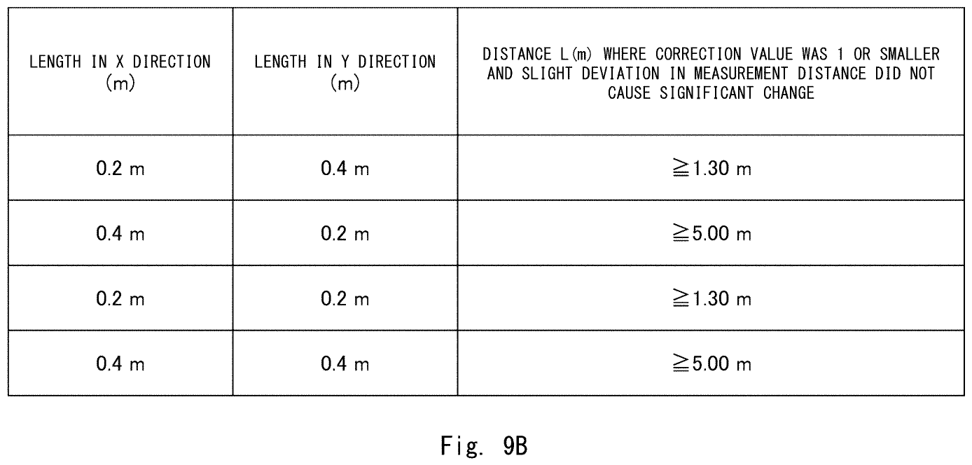

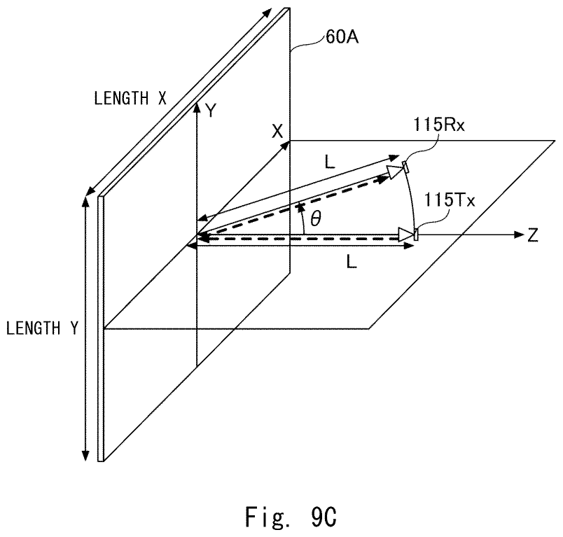

In addition to Examples 2 to 7, the distance between the transmitting antenna 115Tx and the electromagnetic-wave reflecting apparatus 60A on the path of the incident wave and the distance between the electromagnetic-wave reflecting apparatus 60A and the receiving antenna 115Rx on the path of the reflected wave were measured when the electromagnetic-wave reflecting apparatus 60A having a metasurface was set in various sizes (the length in the X direction×the length in the Y direction), the correction value was 1 or smaller, and a slight deviation in the measurement distance did not cause a significant change, and the results shown in FIGS. 9A and 9B were obtained.

Each of FIGS. 9A and 9B is a diagram showing an example of the results of the measurement of the distance from the transmitting antenna 115Tx to the electromagnetic-wave reflecting apparatus 60A on the path of an incident wave and the distance from the electromagnetic-wave reflecting apparatus 60A to the receiving antenna 115Rx on the path of a reflected wave when the correction value was 1 or smaller and a slight deviation in the measurement distance did not cause a significant change regarding the electromagnetic-wave reflecting apparatus 60A. The fact that a significant change was not caused means that the deviation in the measurement distance is a deviation that did not cause a practical problem in calculating power reflection efficiency. FIG. 9C is a diagram showing an example of a configuration of a reflection surface of the electromagnetic-wave reflecting apparatus 60A. The rectangular reflection surface of the electromagnetic-wave reflecting apparatus 60A has a length (width) of X (m) in the X direction and a length of Y (m) in the Y direction. In FIG. 9C, with respect to the electromagnetic-wave reflecting apparatus 60A, the transmitting antenna 115Tx is positioned in a direction in which the incident angle is 0 degrees, and the receiving antenna 115Rx is positioned in a direction in which the reflected angle when a radio wave is incident at an incident angle of 0 degrees is θ degrees. As an example, the reflection angle θ has a positive value in the direction indicated by an arrow in FIG. 9C, and a negative value in the opposite side.

FIG. 9A shows an example of the results of the measurement of a distance L between the electromagnetic-wave reflecting apparatus 60A and each of the transmitting antenna 115Tx and the receiving antenna 115Rx (see FIG. 9C) when the electromagnetic-wave reflecting apparatus 60A had the same length in the X direction and the Y direction, the correction value was 1 or smaller, and a slight deviation in the measurement distance did not cause a significant change. The distances L are the results of the measurement of the distance from the transmitting antenna 115Tx to the electromagnetic-wave reflecting apparatus 60A on the path of an incident wave and the distance from the electromagnetic-wave reflecting apparatus 60A to the receiving antenna 115Rx on the path of a reflected wave when the correction value was 1 or smaller and a slight deviation in the measurement distance did not cause a significant change.

When the length of the electromagnetic-wave reflecting apparatus 60A in each of the X and Y directions was 0.3 m, the distance L was 2.85 m or longer. That is, in a case where the length of the electromagnetic-wave reflecting apparatus 60A in each of the X direction and the Y direction was 0.3 m, when the distance L was shorter than 2.85 m, the correction value was greater than 1, and even a slight deviation in the measurement distance in consideration of the accuracy of the installation and the angle of an antenna and a sample sometimes made the correction value much smaller than an actual appropriate correction value; however, when the distance L was 2.85 m or longer, the correction value was 1 or smaller, and even a slight deviation in the measurement distance did not cause a significant change.

When the length of the electromagnetic-wave reflecting apparatus 60A in each of the X direction and the Y direction increased from 0.3 m to 1.0 m, the distance L increased from 2.85 m to 31.5 m. That is, in a case where the length of the electromagnetic-wave reflecting apparatus 60A in each of the X direction and the Y direction was 1.0 m, when the distance L was shorter than 31.5 m, the correction value was greater than 1, and even a slight deviation in the measurement distance sometimes made the correction value much smaller than an actual appropriate correction value; however, when the distance L was 31.5 m or longer, the correction value was 1 or smaller, and even a slight deviation in the measurement distance did not cause a significant change.

FIG. 9B shows an example of the results of the measurement of a distance L between the electromagnetic-wave reflecting apparatus 60A and each of the transmitting antenna 115Tx and the receiving antenna 115Rx when the electromagnetic-wave reflecting apparatus 60A had the same length or different lengths in the X direction and the Y direction, the correction value was 1 or smaller, and a slight deviation in the measurement distance did not cause a significant change.

When the length of the electromagnetic-wave reflecting apparatus 60A in the X direction was 0.2 m and the length thereof in the Y direction was 0.4 m, the distance L between the electromagnetic-wave reflecting apparatus 60A and each of the transmitting antenna 115Tx and the receiving antenna 115Rx when the correction value was 1 or smaller and a slight deviation in the measurement distance did not cause a significant change was 1.3 m. That is, in a case where the length of the electromagnetic-wave reflecting apparatus 60A in the X direction was 0.2 m and the length thereof in the Y direction was 0.4 m, when the distance L was shorter than 1.30 m, the correction value was greater than 1, and even a slight deviation of the measurement distance sometimes made the correction value much smaller than an actual appropriate correction value; however, when the distance L was 1.30 m or longer, the correction value was 1 or smaller, and even a slight deviation in the measurement distance did not cause a significant change.

In a case where the length of the electromagnetic-wave reflecting apparatus 60A in the X direction was 0.4 m and the length thereof in the Y direction was 0.2 m, when the distance L was 5.00 m or longer, the correction value was greater than 1, and when the distance L was 5.00 m or longer, the correction value was 1 or smaller, and even a slight deviation in the measurement distance did not cause a significant change. The distance L in this case was about four times longer than the distance L when the length of the electromagnetic-wave reflecting apparatus 60A in the X direction was 0.2 m and the length thereof in the Y direction was 0.4 m.

Further, in a case where the length of the electromagnetic-wave reflecting apparatus 60A in the X direction was 0.2 m and the length thereof in the Y direction was 0.2 m, when the distance L was shorter than 1.30 m, the correction value was greater than 1, and even a slight deviation in the measurement distance sometimes made the correction value much smaller than an actual appropriate correction value; however, when the distance L was 1.30 m or longer, the correction value was 1 or smaller, and even a slight deviation in the measurement distance did not cause a significant change. The distance L in this case was the same as the distance L when the length of the electromagnetic-wave reflecting apparatus 60A in the X direction was 0.2 m and the length thereof in the Y direction was 0.4 m.

Further, in a case where the length of the electromagnetic-wave reflecting apparatus 60A in the X direction was 0.4 m and the length thereof in the Y direction was 0.4 m, when the distance L was shorter than 5.00 m, the correction value was greater than 1, and even a slight deviation in the measurement distance sometimes made the correction value much smaller than an actual appropriate correction value; however, when the distance L was 5.00 m or longer, the correction value was 1 or smaller, and even a slight deviation in the measurement distance did not cause a significant change. The distance L in this case was the same as the distance L when the length of the electromagnetic-wave reflecting apparatus 60A in the X direction was 0.4 m and the length thereof in the Y direction was 0.2 m.

From the results shown in FIG. 9B, it was found that the length of the electromagnetic-wave reflecting apparatus 60A in the X direction is more greatly affected by the increase in the distance L than the length thereof in the Y direction.

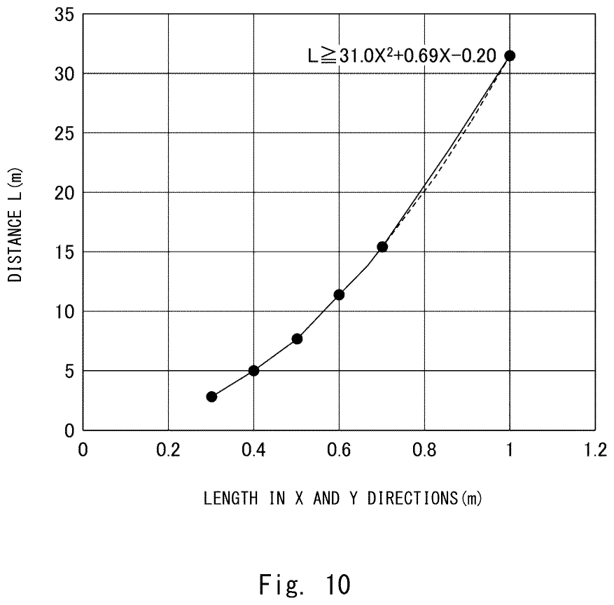

FIG. 10 is a diagram showing an example of a result in which a quadratic curve is fitted to the results shown in FIG. 9A. In FIG. 10, the horizontal axis indicates the lengths (m) of the electromagnetic-wave reflecting apparatus 60A in the X direction and the Y direction. Note that the lengths of the electromagnetic-wave reflecting apparatus 60A in the X direction and the Y direction are equal to each other (X=Y). Further, the vertical axis indicates the distance L.

The fitted quadratic curve can be expressed by the following expression (3).

[Expression 3]

L=31.0X²+0.69X−0.20(m) (3)

In a case where the lengths of the electromagnetic-wave reflecting apparatus 60A in the X direction and the Y direction are equal to each other and both of them are X (m), when the distance L is longer than or equal to the distance L expressed by the expression (3), the correction value was 1 or smaller, and even a slight deviation in the measurement distance did not cause a significant change. Therefore, the following expression (4) only needs to be satisfied between the length (m) of the electromagnetic-wave reflecting apparatus 60A in each of the X direction and the Y direction and the distance L.

[Expression 4]

L≥31.0X²+0.69X−0.20(m) (4)

That is, in a case where the lengths of the electromagnetic-wave reflecting apparatus 60A in the X direction and the Y direction are equal to each other (X=Y), when the distance L between the electromagnetic-wave reflecting apparatus 60A and each of the transmitting antenna 115Tx and the receiving antenna 115Rx is set so that the distance L satisfies the expression (4), the power reflection efficiency H (=Γ1/Γ2) obtained for the electromagnetic-wave reflecting apparatus 60A can be corrected similarly to the results of Examples 2 to 4 of the results of experiments (Part 1).

Further, from the results show in FIG. 9B, it is the length of the electromagnetic-wave reflecting apparatus 60A in the X direction which was greatly affected by the increase in the distance L, and therefore, the expression (4) can be considered as follows. That is, as shown in FIG. 9C, in a case where the length (the width) of the rectangular reflection surface of the electromagnetic-wave reflecting apparatus 60A in the X direction is X (m), when the distance L between the electromagnetic-wave reflecting apparatus 60A and each of the transmitting antenna 115Tx and the receiving antenna 115Rx is set so that the distance L satisfies the expression (4), the power reflection efficiency H (=Γ1/Γ2) obtained for the electromagnetic-wave reflecting apparatus 60A can be corrected similarly to the results of Examples 2 to 4 of the results of experiments (Part 1).

### Effects

A method for measuring received power includes: a first process (Step S1) of, in an anechoic chamber 101 in which a VNA 110 connected to a transmitting antenna 115Tx and a receiving antenna 115Rx of which relative positions are fixed is disposed, causing the transmitting antenna 115Tx to transmit a radio wave in a predetermined band selected from frequency bands of 1 MHz or higher and 300 GHz or lower, and making the radio wave incident on an electromagnetic-wave reflecting apparatus 60 (60A or 60B) at a first specified incident angle; a second process (Step S2) of receiving a reflected wave of the radio wave incident on the electromagnetic-wave reflecting apparatus 60 (60A or 60B) in the first process by the receiving antenna 115Rx disposed in a direction of a first specified reflection angle with respect to the electromagnetic-wave reflecting apparatus 60 (60A or 60B), and measuring first received power in a specified frequency range by the VNA 110; a third process (Step S3) of, in the anechoic chamber 101, causing the transmitting antenna 115Tx to transmit a radio wave in the predetermined band and making the radio wave incident on an electromagnetic-wave reflecting apparatus 60C composed of a perfect conductor at a second specified incident angle; and a fourth process (Step S4) of receiving a reflected wave of the radio wave incident on the electromagnetic-wave reflecting apparatus 60C composed of a perfect conductor in the third process by the receiving antenna 115Rx disposed in a direction of a second specified reflection angle with respect to the electromagnetic-wave reflecting apparatus 60C, and measuring second received power in the specified frequency range by the VNA 110. Therefore, the received power of the electromagnetic-wave reflecting apparatus 60 (60A or 60B) having a metasurface or a regular reflection surface and the electromagnetic-wave reflecting apparatus 60C composed of a perfect conductor can be measured under the same reflection condition by using the VNA 110.

Thus, it is possible to provide a method for measuring received power by which it is possible to appropriately measure received power in the electromagnetic-wave reflecting apparatus 60 having a metasurface or a regular reflection surface. Further, it is possible to provide a program for measuring received power by which it is possible to appropriately measure received power in the electromagnetic-wave reflecting apparatus 60 having a metasurface or a regular reflection surface.

Further, an angle formed by the transmitting antenna 115Tx and the receiving antenna 115Rx with respect to the electromagnetic-wave reflecting apparatus 60 (60A or 60B) in the first process (Step S1) and the second process (Step S2) may be equal to an angle formed by the transmitting antenna 115Tx and the receiving antenna 115Rx with respect to the electromagnetic-wave reflecting apparatus 60C composed of a perfect conductor in the third process (Step S3) and the fourth process (Step S4). Therefore, the received power can be more reliably measured under the same reflection condition by using the VNA 110.

A method for calculating power reflection efficiency includes: one of the above methods for measuring received power; a fifth process (Step S5) of calculating a first power reflection coefficient Γ1 of the electromagnetic-wave reflecting apparatus 60 (60A or 60B) and a second power reflection coefficient Γ2 of the electromagnetic-wave reflecting apparatus 60C composed of a perfect conductor based on a first received power P1 and a second received power P2, respectively; and a sixth process (Step S6) of calculating power reflection efficiency Γ1/Γ2 of the electromagnetic-wave reflecting apparatus 60 (60A or 60B) by dividing the first power reflection coefficient Γ1 by the second power reflection coefficient Γ2. Therefore, the power reflection efficiency Γ1/Γ2 of the electromagnetic-wave reflecting apparatus 60 (60A or 60B) can be calculated by using the VNA 110. Further, by executing a program for calculating power reflection efficiency, the power reflection efficiency Γ1/Γ2 of the electromagnetic-wave reflecting apparatus 60 (60A or 60B) can be calculated by using the VNA 110.

Further, the electromagnetic-wave reflecting apparatus 60 may be an electromagnetic-wave reflecting apparatus 60B which performs specular reflection, and the first specified incident angle, the first specified reflection angle, the second specified incident angle, and the second specified reflection angle may all be equal to each other. Therefore, the power reflection efficiency Γ1/Γ2 of the electromagnetic-wave reflecting apparatus 60 (60A or 60B) can be more reliably calculated by using the VNA 110 under the same reflection condition.

Further, the electromagnetic-wave reflecting apparatus 60 may be an electromagnetic-wave reflecting apparatus 60A which performs non-specular reflection, and the sum of the first specified incident angle and the first specified reflection angle and the sum of the second specified incident angle and the second specified reflection angle may be equal to each other. Therefore, the power reflection efficiency Γ1/Γ2 of the electromagnetic-wave reflecting apparatus 60A can be more reliably calculated by using the VNA 110 under the same reflection condition.

Further, the method for calculating power reflection efficiency may further include a seventh process (Step S7) of correcting the power reflection efficiency Γ1/Γ2 of the electromagnetic-wave reflecting apparatus 60A which performs non-specular reflection by dividing, using a correction value |EMR/EPEC|² obtained based on a reflected electric field EMR in an ideal metasurface with no reflection loss and a reflected electric field EPEC in a reflection surface composed of a perfect conductor, the power reflection efficiency Γ1/Γ2 of the electromagnetic-wave reflecting apparatus 60A which performs non-specular reflection by the correction value |EMR/EPEC|². Therefore, the power reflection efficiency Γ1/Γ2 of the electromagnetic-wave reflecting apparatus 60A in which the incident angle and the reflection angle are different from each other can be appropriately corrected by using the VNA 110.

Further, the reflection surface of the electromagnetic-wave reflecting apparatus 60A which performs non-specular reflection may have a rectangular shape having a width of X (m), a distance between the electromagnetic-wave reflecting apparatus 60A which performs non-specular reflection and a transmitting antenna 115Tx on a path of an incident wave may be equal to a distance between the electromagnetic-wave reflecting apparatus 60A which performs non-specular reflection and a receiving antenna 115Rx on a path of a reflected wave, each of the distances may be L (m), and a condition of the distance L when the correction value is 1 or smaller may be expressed by the following expression (5).

[Expression 5]

L≥31.0X²+0.69X−0.20(m) (5)

By setting the length X (m) of the reflection surface of the electromagnetic-wave reflecting apparatus 60A which performs non-specular reflection and the distance L so as to satisfy the expression (5), the correction value becomes 1 or smaller, and a slight deviation in the measurement distance does not cause a significant change, and hence the power reflection efficiency H (=Γ1/Γ2) obtained for the electromagnetic-wave reflecting apparatus 60A can be corrected.

Although an illustrative method for measuring received power and an illustrative method for calculating power reflection efficiency according to the present disclosure have been described, the present disclosure is not limited to the embodiments specifically disclosed, and various modifications and changes can be made without departing from the scope of the claims.

The above-described program can be stored and supplied to a computer using any of various types of non-transitory computer readable media. The non-transitory computer readable media include various types of tangible storage media. Examples of the non-transitory computer readable media include a magnetic recording medium (for example, a flexible disk, a magnetic tape, or a hard disk drive), a magneto-optical recording medium (for example, a magneto-optical disc), a compact disc-read only memory (CD-ROM), a CD-R, a CD-R/W, and a semiconductor memory (for example, a mask ROM, a programmable ROM (PROM), an erasable PROM (EPROM), a flash ROM, or a random-access memory (RAM)). The program may be supplied to the computer using any of various types of transitory computer readable media. Examples of the transitory computer-readable media include electrical signals, optical signals, and electromagnetic waves. The transitory computer readable medium can supply the programs to the computer via a wired communication line such as electric wires and optical fibers, or a wireless communication line.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A method for measuring received power, the method comprising:
a first process of, in an anechoic chamber in which a vector network analyzer connected to a transmitting antenna and a receiving antenna of which relative positions are fixed is disposed, causing the transmitting antenna to transmit a radio wave in a predetermined band selected from frequency bands of 1 MHz or higher and 300 GHz or lower, and making the radio wave incident on an electromagnetic-wave reflecting apparatus at a first specified incident angle;
a second process of receiving a reflected wave of the radio wave incident on the electromagnetic-wave reflecting apparatus in the first process by the receiving antenna disposed in a direction of a first specified reflection angle with respect to the electromagnetic-wave reflecting apparatus, and measuring first received power in a specified frequency range by the vector network analyzer;
a third process of, in the anechoic chamber, causing the transmitting antenna to transmit a radio wave in the predetermined band and making the radio wave incident on a reflection plate including a metal reflection surface at a second specified incident angle; and
a fourth process of receiving a reflected wave of the radio wave incident on the metal reflection surface in the third process by the receiving antenna disposed in a direction of a second specified reflection angle with respect to the reflection plate including the metal reflection surface, and measuring second received power in the specified frequency range by the vector network analyzer.

2. The method for measuring received power according to claim 1, wherein an angle formed by the transmitting antenna and the receiving antenna with respect to the electromagnetic-wave reflecting apparatus in the first process and the second process is equal to an angle formed by the transmitting antenna and the receiving antenna with respect to the reflection plate including the metal reflection surface in the third process and the fourth process.

3. A method for calculating power reflection efficiency, the method comprising:
the method for measuring received power according to claim 1;
a fifth process of calculating a first power reflection coefficient Γ1 of the electromagnetic-wave reflecting apparatus and a second power reflection coefficient Γ2 of the reflection plate including the metal reflection surface based on the first received power A and the second received power B, respectively; and
a sixth process of calculating power reflection efficiency Γ1/Γ2 of the electromagnetic-wave reflecting apparatus by dividing the first power reflection coefficient Γ1 by the second power reflection coefficient Γ2.

4. The method for calculating power reflection efficiency according to claim 3, wherein
the electromagnetic-wave reflecting apparatus is a reflecting apparatus configured to perform specular reflection, and
the first specified incident angle, the first specified reflection angle, the second specified incident angle, and the second specified reflection angle are all equal to each other.

5. The method for calculating power reflection efficiency according to claim 3, wherein
the electromagnetic-wave reflecting apparatus is a reflecting apparatus configured to perform non-specular reflection, and
a sum of the first specified incident angle and the first specified reflection angle and a sum of the second specified incident angle and the second specified reflection angle are equal to each other.

6. The method for calculating power reflection efficiency according to claim 5, further comprising a seventh process of correcting the power reflection efficiency Γ1/Γ2 of the electromagnetic-wave reflecting apparatus configured to perform non-specular reflection by dividing, using a correction value |EMR/EPEC|² obtained based on a reflected electric field EMR in an ideal metasurface with no reflection loss and a reflected electric field EPEC in a reflection surface composed of a perfect conductor, the power reflection efficiency Γ1/Γ2 of the electromagnetic-wave reflecting apparatus configured to perform non-specular reflection by the correction value |EMR/EPEC|².

7. The method for calculating power reflection efficiency according to claim 6, wherein
the reflection surface of the electromagnetic-wave reflecting apparatus configured to perform non-specular reflection has a rectangular shape having a width of X (m),
a distance between the electromagnetic-wave reflecting apparatus configured to perform non-specular reflection and a transmitting antenna on a path of an incident wave is equal to a distance between the electromagnetic-wave reflecting apparatus configured to perform non-specular reflection and a receiving antenna on a path of a reflected wave, and each of the distances is L (m), and
a condition of the distance L when the correction value becomes 1 or smaller is expressed by the following expression (1).
[Expression 1]
L≥31.0X²+0.69X−0.20(m) (1)

8. A non-transitory computer readable medium storing a program for measuring received power, wherein a computer executes:
a first process of, in an anechoic chamber in which a vector network analyzer connected to a transmitting antenna and a receiving antenna of which relative positions are fixed is disposed, causing the transmitting antenna to transmit a radio wave in a predetermined band selected from frequency bands of 1 MHz or higher and 300 GHz or lower, and making the radio wave incident on an electromagnetic-wave reflecting apparatus at a first specified incident angle;
a second process of receiving a reflected wave of the radio wave incident on the electromagnetic-wave reflecting apparatus in the first process by the receiving antenna disposed in a direction of a first specified reflection angle with respect to the electromagnetic-wave reflecting apparatus, and measuring first received power in a specified frequency range by the vector network analyzer;
a third process of, in the anechoic chamber, causing the transmitting antenna to transmit a radio wave in the predetermined band and making the radio wave incident on a reflection plate including a metal reflection surface at a second specified incident angle; and
a fourth process of receiving a reflected wave of the radio wave incident on the metal reflection surface in the third process by the receiving antenna disposed in a direction of a second specified reflection angle with respect to the reflection plate including the metal reflection surface, and measuring second received power in the specified frequency range by the vector network analyzer.

9. A non-transitory computer readable medium storing a program for calculating power reflection efficiency, wherein a computer executes:
the program for measuring received power according to claim 8;
a fifth process of calculating a first power reflection coefficient Γ1 of the electromagnetic-wave reflecting apparatus and a second power reflection coefficient Γ2 of the reflection plate including the metal reflection surface based on the first received power A and the second received power B, respectively; and
a sixth process of calculating power reflection efficiency Γ1/Γ2 of the electromagnetic-wave reflecting apparatus by dividing the first power reflection coefficient Γ1 by the second power reflection coefficient Γ2.
